(19) United States
(12) Patent Application Publication
(10) Pub. No.: US 2026/0130063 A1
(43) Pub. Date: May 7, 2026

(54) DISPLAY DEVICE

(71) Applicant: SK hynix Inc, Icheon-si (KR)

(72) Inventors: Young Hwan HYEON, Icheon-si (KR); Jin Su LIM, Icheon-si (KR); Young Su LEE, Icheon-si (KR); Ju Sang LEE, Icheon-si (KR)

(21) Appl. No.: 19/084,457

(22) Filed: Mar. 19, 2025

(30) Foreign Application Priority Data
Nov. 7, 2024 (KR) 10-2024-0156888

(51) Int. Cl. H10K 59/123; H10K 59/131; H10K 59/80

(52) U.S. Cl. CPC H10K 59/123; H10K 59/131; H10K 59/80518; H10K 59/878

(57) ABSTRACT

A display device is provided to include a first insulating layer disposed over a substrate; a circuit area disposed in the first insulating layer; a connection electrode disposed on the first insulating layer and electrically connected to the circuit area; a second insulating layer disposed on the connection electrode; a first electrode pattern disposed on the second insulating layer and electrically connected to the connection electrode; a third insulating layer disposed on the first electrode pattern; a second electrode pattern disposed on the third insulating layer in a first through hole of the third insulating layer and electrically connected to the first electrode pattern; a fourth insulating layer disposed on the second electrode pattern; and a third electrode pattern disposed on the fourth insulating layer and in a second through hole of the fourth insulating layer, the third electrode pattern electrically connected to the second electrode pattern.

### PRIORITY CLAIM AND CROSS-REFERENCE TO RELATED APPLICATIONS

This patent document claims the priority and benefits of Korean Patent Application No. 10-2024-0156888, filed on Nov. 7, 2024, the disclosure of which is incorporated by reference in its entirety as part of the disclosure of this patent document.

### TECHNICAL FIELD

Embodiments of the disclosed technology relate to a display device.

### BACKGROUND

As the information society develops, various simplify demands for display devices that display images are increasing and various types of display devices, such as liquid crystal displays and organic light emitting diode displays, are being used.

Among such display devices, an organic light emitting diode display is self-luminous and has superior viewing angles and contrast ratios compared to a liquid crystal display (i.e., LCD). The organic light emitting diode display does not require a separate backlight so that it can be lightweight and thin, and has the advantage of lower power consumption. In addition, the organic light emitting display has the advantages of driving at low direct current voltages, a fast response speed and especially low manufacturing costs.

Recently, there is an increasing demand for display devices for various applications including, e.g., applications for augmented reality (i.e., AR), virtual reality (i.e., VR), and others in which ultra-high display resolutions are desirable by using light emitting display devices.

### SUMMARY

Some embodiments of the present disclosure may provide a display device including a first through hole or a second through hole which has at least two inclined surfaces with different inclinations, so that an electrode pattern deposited within the first through hole or the second through hole is not interrupted.

Some implementations of the disclosed technology provide a display device in which a dark sop defect (or malfunction) of an organic light emitting element is improved by ensuring that the electrode pattern deposited within the first through hole or the second through hole is not broken.

Some implementations of the disclosed technology provide a display device that may induce efficient and precise microcavities in each sub-pixel because a planarization process is omitted in a process of depositing the electrode pattern within the first through hole or the second through hole.

In one aspect, a display device may include a substrate; a first insulating layer disposed over the substrate; a circuit area disposed in the first insulating layer; a connection electrode disposed on the first insulating layer and electrically connected to the circuit area; a second insulating layer disposed on the connection electrode; a first electrode pattern disposed on the second insulating layer and electrically connected to the connection electrode; a third insulating layer disposed on the first electrode pattern; a second electrode pattern disposed on the third insulating layer in a first through hole of the third insulating layer and electrically connected to the first electrode pattern; a fourth insulating layer disposed on the second electrode pattern; and a third electrode pattern disposed on the fourth insulating layer and in a second through hole of the fourth insulating layer, the third electrode pattern electrically connected to the second electrode pattern, wherein at least one of the first through hole or the second through hole includes at least two inclined surfaces having slopes different from each other.

In another aspect of the present disclosure, a display device may include a substrate; a first sub-pixel, a second sub-pixel and a third sub-pixel that are defined on the substrate, each of the first sub-pixel, the second sub-pixel, and the third sub-pixel configured to emit a corresponding colored light; a first reflective electrode disposed on the substrate of the first sub-pixel; first connection electrodes disposed on the substrate of the first sub-pixel to the third sub-pixel; a first insulating layer disposed on the first reflective electrode and the first connection electrodes; second connection electrodes disposed on the first insulating layer of the first sub-pixel to the third sub-pixel; a second reflective electrode disposed on the first insulating layer of the second sub-pixel; a second insulating layer disposed on the second reflective electrode and the second connection electrodes; third connection electrodes disposed on the second insulating layer of the first sub-pixel to the third sub-pixel; a third reflective electrode disposed on the second insulating layer of the third sub-pixel; a first electrode disposed on the third connection electrodes and the third reflective electrode; a common light emitting layer disposed on the first electrode; and a second electrode disposed on the common light emitting layer, wherein a distance between the first reflective electrode and the second electrode is greater than a distance between the second reflective electrode and the second electrode, a distance between the second reflective electrode and the second electrode is greater than a distance between the third reflective electrode and the second electrode, the first insulating layer comprises a third through hole and the second insulating layer comprises a second through hole, and the first through hole or the second through hole comprises at least two inclined surfaces having slopes different from each other.

According to the embodiments of the present disclosure, the display device may include a first through hole or a second through hole which has at least two inclined surfaces with different inclinations. Accordingly, the electrode pattern deposited within the first through hole or the second through hole may not be interrupted.

Furthermore, in the display device according to the embodiments of the present disclosure, a dark sop defect (or malfunction) of an organic light emitting element may be improved by ensuring that the electrode pattern deposited within the first through hole or the second through hole is not broken.

Still further, the display device according to the embodiments of the present disclosure may induce efficient and precise microcavities in each sub-pixel because the planarization process is omitted in the process of depositing the electrode pattern within the first through hole or the second through hole.

In addition to the above-described effects, specific effects of the technical features disclosed in this patent document will be described together with the following detailed description of examples of embodiments for implementing the disclosed features in this patent document.

### BRIEF DESCRIPTION OF THE DRAWINGS

FIG. 1 is a block view showing a display device based on some implementations of the disclosed technology.

FIG. 2 is a cross-sectional view of pixels shown in FIG. 1.

FIG. 3 is a cross-sectional view of an organic light emitting element shown in FIG. 2.

FIG. 4 is a cross-sectional view of an organic light emitting element based on a modified example of FIG. 3.

FIG. 5 is an enlarged cross-sectional view of Q1 area shown in FIG. 2.

FIGS. 6 to 13 cross-sectional views for process steps of a display panel based on some implementations of the disclosed technology.

FIG. 14 is a cross-sectional view of a display device based on some implementations of the disclosed technology.

FIG. 15 is a cross-sectional view of a display device based on some implementations of the disclosed technology.

FIG. 16 is a cross-sectional view of a display device based on some implementations of the disclosed technology.

FIG. 17 is a cross-sectional view of a display device based on some implementations of the disclosed technology.

FIG. 18 is a cross-sectional view of a display device based on some implementations of the disclosed technology.

### DETAILED DESCRIPTION

Hereinafter, a display device according to embodiments of the present disclosure will be described, referring to the accompanying drawings.

Below, preferred embodiments according to the disclosure are specifically described with reference to the accompanying drawings. In the drawings, identical reference numerals can denote identical or similar components.

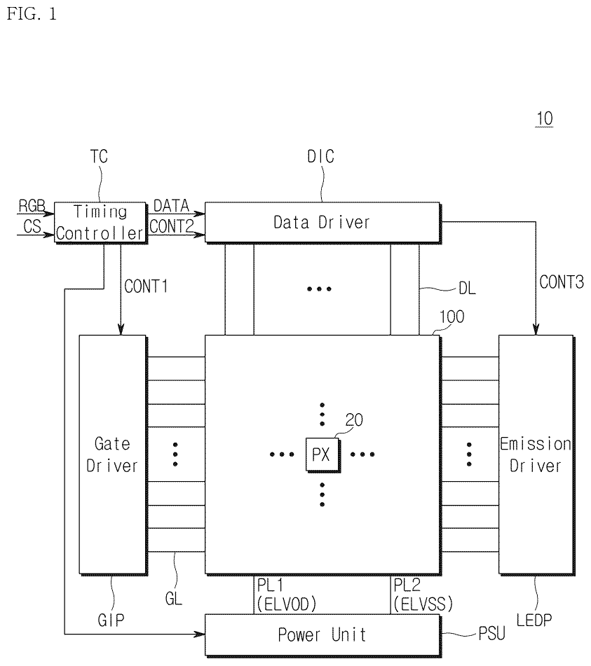

FIG. 1 is a block view showing a display device according to one embodiment.

Referring to FIG. 1, an electronic device 10 may include a display panel 100 that includes panel pixels 20 which emit light for displaying images, a timing controller TC for controlling the timing of the panel pixels 20, a gate driver GIP coupled to the display panel 100, a data driver DIC coupled to the display panel 100, a light emission driver LEDP coupled to the display panel 100, and a power unit PSU coupled to the display panel 100 to supply electric power to the panel pixels 20. The timing controller TC, the gate driver GIP, the data driver DIC, the light emission driver LEDP the power unit PSU and the display panel 100 may be said as components provided in the display device 10.

The timing controller TC may be configured to receive an image signal RGB with color information for each panel pixel 20 (e.g., colors represented by the red (R), green (G) and blue (B) constituent color components) and a control signal CS from an external host system, etc. an image signal RGB may include multiple grayscale data. The control signal CS may include a horizontal synchronization signal, a vertical synchronization signal and a main clock signal, for example.

The timing controller TC may process the image signal RGB and the control signal CS to fit operation conditions of the display panel 100, thereby generating and outputting image data DATA, a gate drive control signal CONT1, a data drive control signal CONT2, a light emission drive control signal CONT3, and a power supply control signal CONT4.

The gate drive control signal CONT1 may include scan timing control signals such as a gate start pulse, a gate shift clock and a gate output enable signal. The data drive control signal CONT2 may include data timing control signals such as a source sampling clock, a polarity signal and a source output enable signal.

The gate driver GIP may be configured to sequentially output a gate signal for one horizontal period within one frame through a gate line GL in response to the gate drive control signal CONT1 provided from the timing controller TC. Hence, pixel rows connected to each gate line GL may be turned on for one horizontal period. For one horizontal period, a data signal may be applied to the pixel rows turned on by the gate line GL.

The gate driver GIP may be composed of or include stage circuits each connected to a plurality of gate lines GL, and may be configured in the form of a GIP (Gate In Panel) mounted on the display panel 100. Such the gate driver GIP may include a shifter resistor, a level shifter, etc.

The data driver DIC may be configured to convert the digital image data DATA provided from the timing controller TC into an analog data signal based on the data drive control signal CONT2. The data driver DIC may be configured to apply an analog data signal to corresponding panel pixels 20 through the data line DL.

The light emission driver (hereinafter, emission driver) LEDP may be configured to generate light emitting signals based on the light emission drive control signal CONT3 output from the timing controller TC. The emission driver LEDP may provide the generated gate signals to the panel pixels 20 through multiple emission lines.

FIG. 1 shows that the gate driver GIP and the emission driver are separately provided, but other implementations are also possible. For example, the gate driver and the emission driver can be integrated in a single integrated circuit. Hereinafter, the gate driver and the emission driver are integrated, and collectively referred to as the gate driver GIP.

The power unit PSU may be configured to covert a voltage input from the outside into a high potential voltage ELVDD and a low potential voltage ELVSS, which are standard power supplies used to provide power inside the electronic device 10, based on the power supply control signal CONT4. The power unit PSU may be configured to output the generated drive voltages ELVDD and ELVSS to the components through the power lines PL1 and PL2.

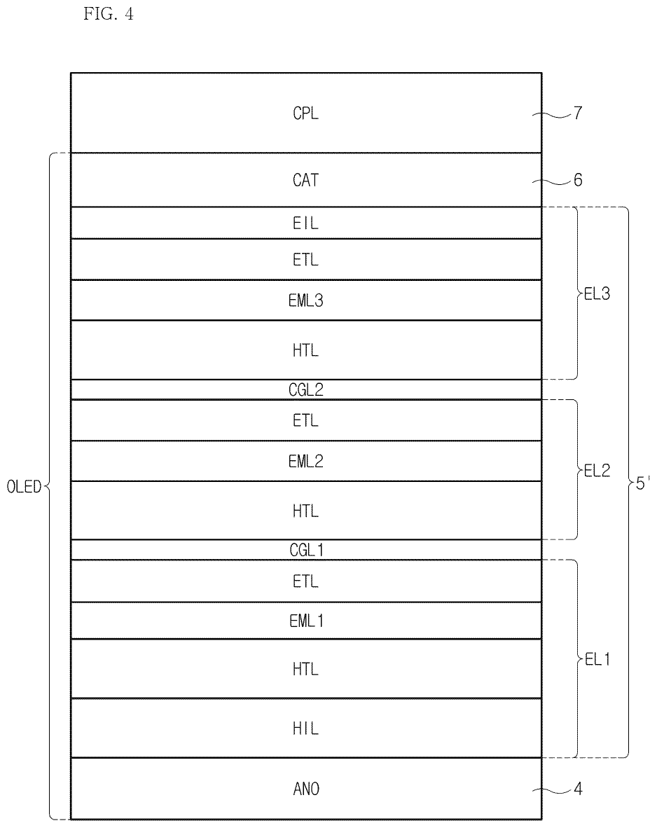

In the electronic device 10 according to one embodiment, the timing controller TC, the data driver DIC, the gate driver GIP, the power unit PSU may be embedded or included in the display panel 100. In a process of forming the display panel 100, circuits composing the timing controller TC, the data driver DIC, the gate driver GIP and the power unit PSU, respectively, may be formed together. The timing controller TC, the data driver DIC, the gate driver GIP, the power unit PSU may be mounted on a substrate (see 2 of FIG. 4). In some embodiments, the timing controller TC, the data driver DIC, the gate driver GIP and the power unit PSU may be implemented as a separate chip CHIP provided separately from the display panel 100.

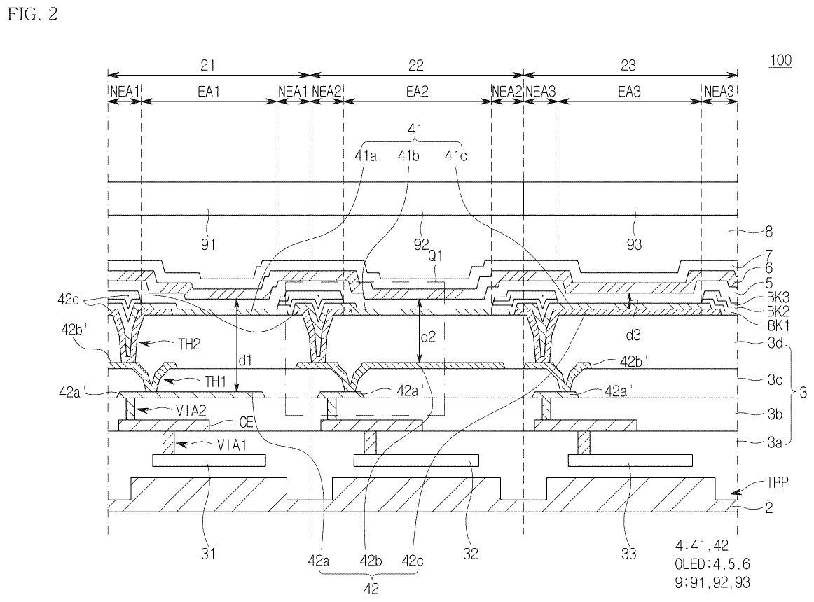

FIG. 2 is a cross-sectional view of one example for implementing each of the panel pixels 20 shown in FIG. 1.

Referring to FIG. 2, the display panel 100 according to this embodiment may include a substrate 2, a first electrode 4, a common light emitting layer 5 and a second electrode 6. The first electrode 4, the common light emitting layer 5 and the second electrode 6 may form an organic light emitting device OLED.

A plurality of sub-pixels 21, 22 and 23 may be formed on the substrate 2. The plurality of sub-pixels may form one panel pixel 20 in the display panel 100 in FIG. 1. A plurality of pixels (see 20 of FIG. 1) may be formed on the substrate 2 to form the display panel 100 in FIG. 1.

The plurality of sub-pixels 21, 22 and 23 may include a first sub-pixels 21, a second sub-pixel 22 and a third sub-pixel 23 that are arranged relative to one another in a spatial sequence or pattern. For example, as shown in the example illustrated in FIG. 2, the first sub-pixel 21, the second sub-pixel 22 and the third sub-pixel 23 are aligned in sequence along a line where the second sub-pixel 22 may be disposed adjacent to one side, for example, the right side, of the first sub-pixel 21, and the third sub-pixel 23 may be disposed adjacent one side, for example, the right side of the second sub-pixel 22.

In some implementations, when arranging two sub-pixels adjacent to each other, there is no other sub-pixel arranged between the two sub-pixels.

The first sub-pixel 21, the second sub-pixel 22, and the third sub-pixel 23 are configured to emit different colored lights from one another. For example, the first sub-pixel 21 may be configured to emit red light R, the second sub-pixel 22 may be configured to emit green light G, and the third sub-pixel 23 may be configured to emit blue light B, but the embodiment is not limited thereto.

FIG. 2 shows that the pixel includes only three sub-pixels 21, 22 and 23, but other implementations are also possible. For example, the pixel may include four sub-pixels. If the pixel includes four sub-pixels, a fourth sub-pixel configured to emit white light W may be further provided.

Each of the first to third sub-pixels 21, 22 and 23 may have the same size. For example, each of the first to third sub-pixels 21, 22 and 23 may be configured to have the same width and the same height.

Each of the sub-pixels 21, 22 and 23 may include emission areas EA1, EA2 and EA3 and non-emission areas NEA1, NEA2 and NEA3. The first sub-pixel 21 may include a first emission area EA1 and a first non-emission area NEA1 adjacent to the first emission area EA1. The second sub-pixel 22 may include a second emission area EA2, a second non-emission area NEA2 disposed adjacent to the second emission area EA2. The third sub-pixel 23 may include a third emission area EA3 and a third non-emission area NEA3 disposed adjacent to the third emission area EA3. Each of the emission areas EA1, EA2 and EA3 may be the same as the area exposed from a bank BK1, BK2 and BK3 of anode electrode 41a, 41b and 41c.

The first electrode 4 may be patterned for each sub-pixel 21, 22 and 23. That is, one first electrode 4 may be formed in the first sub-pixel 21, another first electrode 4 may be formed in the second sub-pixel 22, and a further electrode 4 maybe formed in the third sub-pixel 23. The first electrode 4 may include a reflective electrode 42 and an anode electrode 41. The anode electrode 41 and the reflective electrode 42 may be disposed for each sub-pixel 21, 22 and 23. Th anode electrode 41 may include a first anode electrode 41a disposed in the first sub-pixel 21, a second anode electrode 41b disposed in the second sub-pixel 22, and a third anode electrode 41c disposed in the third sub-pixel 23. The reflective electrode 42 may include a first reflective electrode 42a disposed in the first sub-pixel 21, a second reflective electrode 42b disposed in the second sub-pixel 22, and a third reflective electrode 42b disposed in the third sub-pixel 23. The electrodes 42a, 42b and 42c of the sub-pixels 21, 22 and 23 may be disposed at different heights, respectively.

A bank (see BK1, BK2 and BK3 of FIG. 2) may be disposed on each of the anode electrodes 41a, 41b and 41b. The bank BK1, BK2 and BK3 may be disposed to cover each edge of the anode electrodes 41a, 41b and 41c disposed in the first to third sub-pixels 21, 22 and 23, respectively, thereby distinguishing the first sub-pixel 21, the second sub-pixel 22 and the third sub-pixel 23 from each other.

The display panel 100 may include reflective electrodes 42a, 42b and 42c with different surface heights for each sub-pixel 21, 22 and 23, to improve the light extraction efficiency by using micro cavity characteristics.

The micro cavity characteristics refers to a characteristic in which constructive interference occurs when the distance between the reflective electrodes 42a, 42b and 42c and the second electrode 6 becomes an integer multiple of the half wavelength W2 of light emitted from the sub-pixels 21, 22 and 23 and the light is amplified, and when the reflection and re-reflection process is repeated between the reflective electrodes 42a, 42b and 42c and the second electrode 6, the degree of light amplification continuously increases, thereby improving the external extraction efficiency of light.

The common light emitting layer 5 may be configured to emit white light. For example, the common light emitting layer 5 may be configured with a two-stack structure including a blue light emitting layer, a yellow-green light emitting layer and a charge generation layer, or with a three-stack structure including a blue light emitting layer, a green light emitting layer, a red light emitting layer and a charge generation layer, so as to emit white light. However, the embodiment is not limited thereto and it may be configured with a multiple-stack structure more than three stacks as long as the multi-stack structure is capable of emitting white light.

The common light emitting layer 5 may be provided as the common layers over the entire first to third sub-pixels 21, 22 and 23.

The second electrode 6 may be configured to form an electric field with the anode electrodes 41a, 41b and 41c, and functioned as a cathode. The second electrode 6 may be disposed on an upper surface of a common light emitting layer 5, which is opposite to a lower surface of a common light emitting layer 5 in contact with the anode electrodes 41a, 41b and 41c, and it may be provided as the common layer over the entire first to third sub-pixels 21, 22 and 23.

The second electrode 6 may be provided as a second electrode in the case of a top emission method, but may be provided as a third electrode including a reflective material in the case of a bottom emission method. The second electrode 6 may be formed as a semitransparent electrode to increase light extraction by utilizing micro cavity characteristics. The display device 1 is described as an example in which the second electrode 6 is formed as the semitransparent electrode to increase light extraction efficiency by utilizing micro cavity characteristics in the top emission method.

The color filter layer 9 may be provided in each of the first to third sub-pixels 21, 22 and 23 and configured to block a specific color from the light emitted from the common light emitting layer 5 of each sub pixel 21, 22 and 23. A first color filter 91 provided in the first sub-pixel 21 may be configured to block light of colors except red light R. In this instance, the first color filter 91 may be provided as a red color filter. A second color filter 92 provided in the second sub-pixel 22 may be configured to block light of colors except a green light G. In this instance, the second color filter 92 may be provided as a green color filter. A third color filter 93 provided in the third sub-pixel 23 may be configured to block light of colors except a blue light B. in this instance, the third color filter 93 may be provided as a blue color filter. However, embodiments of the present disclosure are not limited thereto.

The first to third color filters 91, 92 and 93 provided in the first to third sub-pixels 21, 22 and 23, respectively, may be provided in a size identical to the size of each sub-pixel or may be provided in a reduced or enlarged size at a constant ratio to the size of each sub-pixel.

Circuit parts 31, 32 and 33 may be disposed in the non-emission areas NEA1, NEA2 and NEA3 of each sub-pixel 21, 22 and 23. Each of the circuit parts 31, 32 and 33 may include CMOS circuit or a transistor circuit, but the embodiments of the present disclosure are not limited thereto.

The circuit parts 31, 32 and 33 may overlap with the reflective electrodes 42a, 42b and 42c disposed in each of the sub-pixels 21, 22 and 23. The circuit parts 31, 32 and 33 may be electrically connected to the reflective electrodes 42a, 42b and 42c.

Hereinafter, the laminated structure of the display panel 100 according to one embodiment will be described in detail.

The display device 1 according to one embodiment may include a substrate 2, an insulating layer 3, a first electrode 4, banks BK1, BK2 and BK3, a common light emitting layer 5, a second electrode 6, a capping layer 7, an encapsulating layer 8 and a color filter layer 9.

The substrate 2 may be a plastic film, a glass substrate or a semiconductor substrate such as silicon. For example, the substrate 2 may be a semiconductor substrate.

The substrate 2 may be made of or include a transparent material or an opaque material. A first sub-pixel 21, a second sub-pixel 22 and a third sub-pixel 23 may be provided on the substrate 2. The first sub-pixel 21 may be configured to emit red light R, the second sub-pixel 22 may be configured to emit blue light B, and the third sub-pixel 23 may be configured to emit green light G.

The display device 1 according to one embodiment may be configured with a so-called top emission method in which the emitted light is emitted upward, and therefore not only a transparent material but also an opaque material may be used as the material of the substrate 2. Color filters 91, 92 and 93 may be provided on an upper side of the first to third sub-pixels 21, 22 and 23 from which the light is emitted, respectively, to transmit light of the same color.

At least one trench part TRP may be formed on the substrate 2. The substrate 2 may be recessed toward the thickness direction at the trench part TRP. The trench part TRP may be arranged to correspond to the boundary between adjacent sub-pixels 21, 22 and 23. In several embodiments, a plurality of trench parts TRP may be formed in one of the sub-pixels 21, 22 and 23, but embodiments of the present disclosure are not limited thereto. The trench part TRP may improve electrical connection of circuit parts 31, 32 and 33 between adjacent sub-pixels 21, 22 and 23 through the substrate 2.

The insulating layer 3 may be formed on the substrate 2. The insulating layer 3 may include an inorganic insulating material. The insulating layer 3 may include a first insulating layer 3a; a second insulating layer disposed on the first insulating layer 3a; a third insulating layer 3c formed on the second insulating layer 3b; and a fourth insulating layer 3d formed on the third insulating layer 3c.

Within the insulating layer 3, circuit elements including a plurality of circuit parts 31, 32 and 33, various signal wires and capacitors may be provided for each sub-pixel 21, 22 and 23. The circuit parts 31, 32 and 33 may be disposed in the first insulating layer 3a. The signal wires may include a gate line, a data line, a power line and a reference line. The circuit parts 31, 32 and 33 may include a CMOS circuit or a thin film transistor. When the circuit parts 31, 32 and 33 includes a thin film transistor, the thin film transistor may include at least one of a switching thin film transistor, a driving thin film transistor, or a sensing thin film transistor. The switching thin film transistor is switched based on a gate signal supplied to the gate line and configured to supply a data voltage supplied from the data line to the driving thin film transistor.

The driving thin film transistor may be switched based on a data voltage supplied from the switching thin film transistor and configured to generate data current from the power supplied from the power line and supply the generated data current to the first electrode 4.

The sensing thin film transistor may be configured to sense the threshold voltage deviation of the driving thin film transistor, which is the cause of image quality deterioration, and supply the current of the driving thin film transistor to the reference line in response to a sensing control signal supplied from the gate line or a separate sensing line.

The capacitor may be configured to maintain a data voltage supplied to the driving thin film transistor for one frame, and connected to a gate terminal and a source terminal of the driving thin film transistor, respectively.

Each sub-pixel 21, 22 and 23 may be defined by or include the crossing structure of gate lines and data lines. The insulating layer 3 may surround the circuit parts 31, 32 and 33.

A first circuit part 31, a second circuit part 32 and a third circuit part 33 may be arranged for each sub-pixel 21, 22 and 23 within the first insulating layer 3a. The first circuit part 31 may be connected to the first electrode 4 disposed on the first sub-pixel 21 and may supply a driving voltage to emit light of a color corresponding to the first sub-pixel 21. The first circuit part 31, the second circuit part 32 and the third circuit part 33 may be provided on the same layer, but embodiments of the present disclosure are not limited thereto.

The second circuit part 32 may be connected to the first electrode 4 disposed on the second sub-pixel 22, and configured to apply a driving voltage for emitting light of a color corresponding to the second sub-pixel 22.

The third circuit part 33 may be connected to the first electrode disposed on the third sub-pixel 23 and configured to apply a driving voltage for emitting light of a color corresponding to the third sub-pixel 23.

Each of the first sub-pixel 21, the second sub-pixel 22 and the third sub-pixel 23 may supply predetermined current to the light emitting layer based on a data voltage of a data line when a gate signal is input from a gate line, using each of the circuit parts 31, 32 and 33. Accordingly, the light emitting layers of the respective first to third sub-pixels 21, 22 and 23 may emit light with a predetermined brightness based on a predetermined current.

The insulating layer 3 may be configured to protect the circuit parts 31, 32 and 33. The insulating layer 3 may be made of or include an inorganic insulating material, but embodiments of the present disclosure are not limited thereto. The insulating layer 3 may be made of or include an organic insulating material. For example, the insulating material 3 may be made of or include an inorganic material such as silicon nitride (SiNx), silicon oxide (SiOx), or aluminum oxide (Al2O3), but the embodiments of the present disclosure are not limited thereto.

A connection electrode and a plurality of electrode patterns may be disposed on the insulating layer 3. The plurality of electrode patterns may include a connection electrode CE formed on the first insulating layer 3a; a first electrode pattern 42a and 42a′ formed on the second insulating layer 3b; a second electrode pattern 42b and 42b′ formed on the third insulating layer 3c; and a third electrode pattern 42c and 42c′ formed on the fourth insulating layer 3d. In some implementations, the first electrode pattern 42a and 42a′ may include a first reflective electrode 42a and a first connection electrode 42a′. The second electrode pattern 42b and 42b′ may include a second reflective electrode 42b and a second connection electrode 42b′. In some implementations, the third electrode pattern 42c and 42c′ may include a third reflective electrode 42c and a third connection electrode 42c′.

The connection electrode CE may be disposed in each of the sub-pixels 21, 22 and 23. The connection electrodes CE may be disposed in the first sub-pixel 21, the second sub-pixel 22 and the third sub-pixel 23, respectively, and they may be disposed on the first insulating layer 31a. In some implementations, the connection electrodes CE of the sub-pixels 21, 22 and 23 may be electrically connected to the circuit parts 31, 32 and 33 through a first via VIA. The first via VIA1 may include copper Cu or tungsten W, but the embodiments of the present disclosure are not limited thereto. The first via VIA1 may be filled in a hole recessed from the first insulating layer 3a toward the thickness direction. The first insulating layer 3a in which the first via VIA1 is formed may include an inclined surface formed at one inclination angle.

The first reflective electrode 42a and the first connection electrode 42a′ may be disposed on the same layer and include the same material. The second reflective electrode 42b and the second connection electrode 42b′ may be disposed on the same layer, with the same material. The third reflective electrode 42c and the third connection electrode 42c′ may be disposed on the seam layer, with the same material.

Each electrode pattern may include a reflective material for reflecting light. For example, the reflective material may be or include metal but the embodiments of the present disclosure are not limited thereto and it may be or include other materials as long as material is capable of reflecting light. For example, the reflective material may have a laminated structure of alu aluminum (Al), silver (Ag), or aluminum (Al) and titanium (Ti), but the embodiments of the present disclosure are not limited thereto.

Since the reflective electrodes (42: 42a, 42b and 42c) are disposed at positions relatively lower than the common light emitting layer 5, the reflective electrodes (42: 42a, 42b and 42c) may reflect light emitted from the common light emitting layer 5 upward. Here, the upward direction means a direction which can be recognized by a user. For example, the upward direction may mean a direction in which the encapsulation layer 8 or the color filter layer 9 is disposed. Accordingly, the first sub-pixel 21, the second sub-pixel 22 and the third sub-pixel 23 may have improved light efficiency compared to the case where there are no reflective electrodes (42: 42a, 42b and 42c) and the user can perceive a high brightness, e.g., clear image through the improved light efficiency.

The first reflective electrode 42a may be disposed on the second insulating layer 3b in the first sub-pixel 21. The first connection electrodes 42a′ may be disposed on the second insulating layer 3b in each of the sub-pixels 21, 22 and 23, and connected to the first reflective electrode 42a in the first sub-pixel 21. The first connection electrodes 42a′ disposed in each of the sub-pixels 21, 22 and 23 may be electrically connected to the connection electrode CE through a second via VIA2. The second via VIA2 may include copper CU or tungsten W but the embodiments of the present disclosure are not limited thereto. The second via VIA2 may be filled in a hole recessed from the second insulating layer 3b toward the thickness direction. The hole of the second insulating layer 3b in which the second via VIA2 is formed may include one inclined surface.

The first reflective electrode 42a may be disposed on the first emission area EA1 and also on the first non-emission area NEA1. Here, it is shown that the first connection electrode 42a′ is disposed on the first non-emission area NEA1 and some of the first reflective electrode 42a extends even to the first emission area EA1. However, the embodiments of the present disclosure are not limited thereto and the first connection electrode 42a′ may be disposed only on the first non-emission area NEA1.

A third insulating layer 3c may be disposed on the first reflective electrode 42a and the first connection electrode 42a′.

The second reflective electrode 42b may be disposed on the third insulating layer 3c in the second sub-pixel 22, and the second connection electrodes 42b′ may be disposed on the third insulating layer 3c in each of the sub-pixels 21, 22 and 23. The second connection electrodes 42b′ disposed in each of the sub-pixels 21, 22 and 23 may be electrically connected to the first connection electrode 42a′ disposed in a lower area in the first through hole TH1. The third insulating layer 3c may be recessed from the first through hole TH1 toward the thickness direction. In the first sub-pixel 21, the second connection electrode 42b′ may be electrically connected to the first connection electrode 42a′ in the third through hole TH1. In the second sub-pixel 22, the second connection electrode 42b′ may be electrically connected to the first connection electrode 42a′ in the first through hole TH1. In the third sub-pixel 23, the second connection electrode 42b′ may be electrically connected to the first connection electrode 42a′ in the first through hole TH1. It is shown in FIG. 2 that the first through hole TH1 is disposed in the emission areas EA1, EA2 and EA3, but it may also be disposed in the non-emission areas NEA1, NEA2 and NEA3.

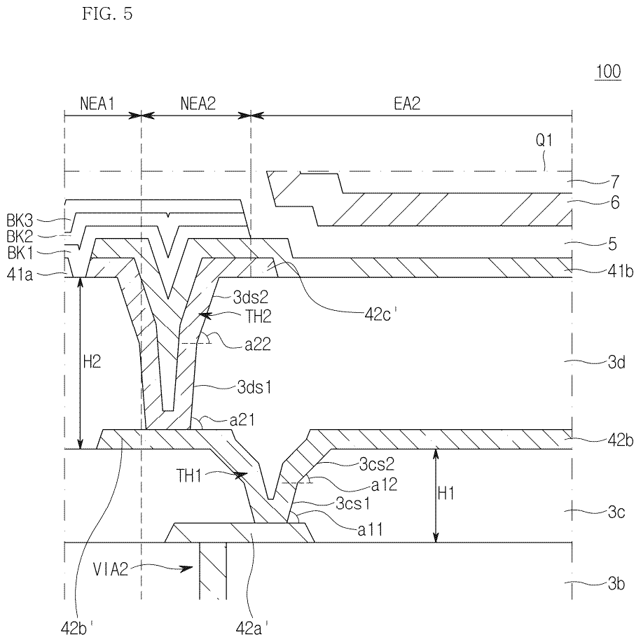

In one embodiment, the first through hole TH1 may include two or more inclined surfaces. That is, the first through hole TH1 may include two or more inclined surfaces having different inclination angles, which will be described later, referring to FIG. 5.

A fourth insulating layer 3d may be disposed on the second reflective electrode 42b and the second connection electrode 42b′.

The third reflective electrode 42b may be disposed on the fourth insulating layer 3d in the third sub-pixel 23. The third connection electrodes 42b may be disposed on the fourth insulating layer 3d in each of the sub-pixels 21, 22 and 23. The third connection electrodes 42c′ disposed in each of the sub-pixels 21, 22 and 23 may be electrically connected to the second connection electrode 42b′ disposed in lower positions in the second through hole TH2. In the second through hole TH2, the fourth insulating layer 3d may be recessed in the thickness direction. In the first sub-pixel 21, the third connection electrode 42c′ may be electrically connected to the second connection electrode 42b′ in the second through hole TH2. In the second sub-pixel 22, the third connection electrode 42c′ may be electrically connected to the second connection electrode 42b′ in the second through hole TH2. In the third sub-pixel 23, the third connection electrode 42c′ may be electrically connected to the second connection electrode 42b′ in the second through hole TH2. It is shown in FIG. 2 that the second through hole TH2 is disposed in the emission areas EA1, EA2 and EA3, but the second through hole TH2 may be disposed in the non-emission areas NEA1, NEA2 and NEA3.

In one embodiment, the second through hole TH2 may include two or more inclined surfaces. That is, the second through hole TH2 may include two or more inclined surfaces having different inclination angles, which will be described later, referring to FIG. 5.

Although not shown in the drawings, a trench (not shown) may be formed in at least one insulating layer 3a, 3b, 3c and 3d. for example, the trench may be formed in the non-emission areas NEA1, NEA2 and NEA3. For example, the trench may be formed through part or all of the fourth insulating layer 3d, but the embodiments of the present disclosure are not limited thereto. The trench may be configured to prevent lateral leakage current LLC due to the common light emitting layer 5 disposed between adjacent two sub-pixels 21, 22 and 23.

As shown in FIG. 2, the distance between the reflective electrodes 42a, 42b and 42c and the second electrode 6 may be different in the emission areas EA1, EA2 and EA3. For example, the distance between the first reflective electrode 42a and the second electrode 6 maya be the largest, followed by the distance between the second reflective electrode 42b and the second electrode 6, and the lastly, the distance between the third reflective electrode 42c and the second electrode 6 may be the smallest.

In this way, the reflective electrodes 42a, 42b and 42c are formed to have various distances (or resonance distances) from the second electrode 6, because the light extraction efficiency of different colors may be improved through reflection and re-reflection between the reflective electrodes 42a, 42b and 42c and the second electrode 6 based on the distance. Accordingly, in the first sub-pixel 21, the light extraction efficiency of red light may be improved. In the second sub-pixel 22, the light extraction efficiency of green light may be improved. In the third sub-pixel 23, the light extraction efficiency of blue light may be improved.

The anode electrode 41 may include a first anode electrode 41a of the first sub-pixel 21, a second anode electrode 41b of the second sub-pixel 22 and a third anode electrode 41b of the third sub-pixel 23. The anode electrodes 41a, 41b and 41c may be disposed on the same layer and include the same material.

The anode electrodes 41a, 41b and 41c may be directly disposed on the third connection electrode 42c′ or the third reflective electrode 42c in each of the sub-pixels 21, 22 and 23. In each of the sub-pixels 21, 22 and 23, the anode electrodes 41a, 41b and 41c may be electrically connected to the third connection electrode 42′c or the third reflective electrode 42c. the anode electrodes 41a, 41b and 41c may be disposed in the emission areas EA1, EA2 and EA3, respectively, and may extend to be disposed even in some of the non-emission areas NEA1, NEA2 and NEA3.

The anode electrodes 41a, 41b and 41c may include a material with high light transmittance. The anode electrodes 41a, 41b and 41b may be provided transparently so that light reflected from the reflective electrodes 42a, 42b and 42c can proceed upward. The anode electrode 41a, 41b and 41c may be made of or include a transparent material, but the embodiments are not limited thereto. It may be provided as a thin film made of or including a metal material as long as it is capable of transmitting light therethrough. For example, the anode electrode 41a, 41b and 41c may include titanium nitride TiN but the embodiments of the present disclosure are not limited thereto. For example, when the anode electrode 41a, 41b and 41c includes TiN, the thickness of the anode electrode may be about 5 nm or less. for example, the thickness of the anode electrode 41a, 41b and 41c may be about 3 nm, but the embodiments are not limited thereto. For example, the anode electrode 41a, 41b and 41b may include a transparent conductive oxide such as ITO or IZO.

A bank may be disposed on the anode electrode 41a, 41b and 41c. The bank may be composed of or include multiple layers, but the embodiments of the present disclosure are not limited thereto. For example, the bank may include three stacked banks BK1, BK2 and BK3.

The banks BK1, BK2 and Bk3 may be made of or include an in organic material such as silicon nitride (SiNx), silicon oxide (SiOx), or aluminum oxide (Al₂O₃), but the embodiments of the present disclosure are not limited thereto. For example, a first bank BK1 may include aluminum oxide Al₂O₃, the second bank BK2 may include silicon oxide SiOx, and the third bank BK3 may include nitride oxide SiNz, but the embodiments of the present disclosure are not limited thereto.

The banks BK1, BK2 and BK3 may be disposed on the non-emission areas NEA1, NEA2 and NEA3. In the non-emission area NEA1, NEA2 and NEA3, the banks BK1, BK2 and BK3 may be configured to expose upper surfaces of the anode electrodes 41a, 41b and 41c to define the emission areas EA1, EA2 and EA3.

The common light emitting layer 5 may be formed on the anode electrodes 41a, 41b and 41c and the banks BK1, BK2 and Bk3. The common light emitting layer 5 may be in contact with upper surfaces of the anode electrodes 41a, 41b and 41c. the common light emitting layer 5 may be in direct contact with the upper surfaces of the anode electrodes 41a, 41b and 41c, the upper surfaces of the banks BK1, BK2 and Bk3 and the upper surface of the insulating layer 3.

The organic light emitting element OLED according to one embodiment may include an anode electrode (41, ANO), a first electrode 4, a second electrode (6, CAT), and a common light emitting layer 5 disposed between the first electrode and the second electrode 6.

The common light emitting layer 5 may be configured to emit white light W. In some implementations, the common light emitting layer 5 may be composed of or include multiple stacks configured to emit light of different colors. Specifically, the common light emitting layer 5 may include a first stack, a second stack and a charge generation layer CGL provided between the first stack and the second stack. The common light emitting layer 5 may be formed in each of the sub-pixels and between the sub-pixels.

The second electrode 6 may be formed on the common light emitting layer 5. The second electrode may function as a cathode of the display panel. The second electrode 6 may be formed in each of the sub-pixels and between the sub-pixels, like the common light emitting layer 5.

In the display panel 100 according to one embodiment, the second electrode 6 may be provided as a semitransparent electrode to implement white light with high light efficiency in the top emission method. Accordingly, a micro cavity effect can be obtained for each of the first to third sub-pixels 21, 22 and 23. Reflection and re-reflection may be repeated between the second electrode 6 and the reflective electrode 42 and then the micro cavity effect can be obtained, thereby improving light extraction efficiency.

Since the second electrode 6 is formed on the upper surface of the common light emitting layer 5, it may be formed along the profile of the common light emitting layer 5. Since the common light emitting layer 5 is formed along the profile of the first electrode 4 in the emission area, the second electrode 6 may be formed along the profile of the first electrode 4. In addition, the capping layer 7 formed on the second electrode 6 may be formed along the profile of the second electrode 6.

The capping layer 7 may be made of or include an inorganic insulating material, but the embodiments are not limited thereto. The capping layer 7 may be disposed on the second electrode 6 and may protect the organic light emitting element OLED.

The encapsulation layer 8 may be formed on the second electrode 6 and configured to prevent external moisture from leaking into the common light emitting layer 5. The encapsulation layer 8 may be made of or include an inorganic insulating material or configured of a stack structure in which an inorganic material and an organic insulating material are alternately stacked, but the embodiments are not limited thereto.

The color filter layer 9 may be formed on the encapsulation layer 8. The color filter layer 9 may include a first color filter 91 of red color R provided in the first sub-pixel; a second color filter 92 of green color G provided in the second sub-pixel 22; and a third color filter 93 of blue light B provided in the third sub-pixel 23, but the embodiments are not limited thereto. Although not shown, a black matrix may be provided between each two of the first to color filters 91, 92 and 93 to prevent color mixing between the sub-pixels.

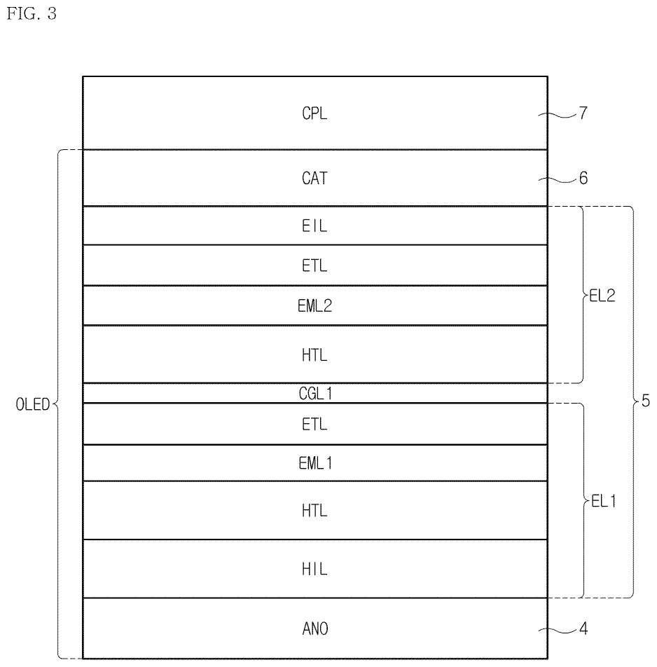

FIG. 3 is a cross-sectional view of an organic light emitting element shown in FIG. 2. FIG. 4 is a cross-sectional view of an organic light emitting element according to a modified example of FIG. 3.

Referring to FIGS. 2 and 3, a common light emitting layer 5 maya include a first stack EL1 provided on a first electrode 4, a second stack EL2 and a first charge generation layer CGL1.

The first stack EL1 may be provided on the first electrode 4, and may have a structure in which a hole injection layer HIL a hole transport layer HTL, a blue B emitting layer EML1, and an electron transport layer ETL are sequentially laminated.

The first stack EL1 may be disposed between the first sub-pixel 21 and the second sub-pixel 22, and even between the second sub-pixel 22 and the third sub-pixel 23.

The first charge generation layer CGL1 may be configured to supply a charge to the first stack EL1 and the second stack EL2. The first charge generation layer CGL1 may include an N-type charge generation layer configured to supply an electron to the first stack EL2; and a P-type charge generation layer configured to supply a hole to the second stack EL2. The N-type charge generation layer may include a metal material as dopant.

The second stack EL2 may be provided on the first stack EL1, and may have a structure in which a hole transport layer (HTL), a yellow green (YG) emitting layer (EML2), an electron transport layer (ETL), and an electron injection layer (EIL) are sequentially stacked.

The second stack EL2 may be disposed between the first sub-pixel 21 and the second sub-pixel 22, and even between the second sub-pixel 22 and the third sub-pixel 23.

As a result, the common light emitting layer 5 may be provided over the entire first to third sub-pixels 21, 22 and 23 as the common layer, as shown in FIGS. 2 and 3.

As shown in FIGS. 2 and 4, a common light emitting layer 5′ of an organic light emitting element OLED according to one embodiment may include a first stack EL1 provided on the first electrode 4, a second stack EL2, a third stack EL3, a first charge generation layer CGL1 disposed between the first stack EL1 and the second stack EL2, and a second charge generation layer CGL2 disposed between the second stack EL2 and the third stack EL3.

The first stack EL1 may be provided on the first electrode 4 and may have a structure in which a hole injection layer HIL, a hole transport layer HTL, a blue B emitting layer EML1 and an electron transport layer ETL are sequentially stacked.

The first stack EL1 may be disposed between the first sub-pixel 21 and the second sub-pixel 22, and even between the second sub-pixel 22 and the third sub-pixel 23, that is, on the banks BK1, BK2 and BK3.

The first charge generation layer CGL1 may be configured to supply a charge to the first stack EL1 and the second stack EL2. The first charge generation layer CGL1 may include an N-type charge generation layer configured to supply an electrode to the first stack EL1; and a P-type charge generation layer configured to supply a hole to the second stack EL2. The N-type charge generation layer may include a metal material as dopant.

The second stack EL1 may be provided on the first stack EL1, and may be composed of or include a structure in which a hole transporting layer HTL, a green light emitting layer EML2, and an electron transporting layer ETL are sequentially stacked.

The second stack EL2 may be disposed between the first sub-pixel 21 and the second sub-pixel 22, and even between the second sub-pixel 22 and the third sub-pixel 23, that is, on the banks BK1, BK2 and BK3.

The second charge generation layer CGL2 may be configured to supply a charge to the second stack EL2 and the third stack EL3. The second charge generation layer CGL2 may include an N-type charge generation layer configured to supply an electrode to the second stack EL2; and a P-type charge generation layer configured to supply a hole to the third stack EL3. The N-type charge generation layer may include a metal material as dopant.

The third stack EL3 may be provided on the second stack EL2, and may be composed of or include a structure in which a hole transporting layer HTL, a red R light emitting layer EML3, an electron transporting layer ETL and an electron injecting layer EIL are sequentially stacked.

As shown in FIGS. 2, 3 and 4, the charge generation layer CGL1 and CGL2 may be disposed between the first sub-pixel 21 and the second sub-pixel 22 and even between the second sub-pixel 22 and the third sub-pixel 23. In the display panel 100 according to one embodiment, since the common light emitting layer 5 is disposed even between any two of the sub-pixels 21, 22 and 23, one sub-pixel emits light and then a lateral leakage current might occur to the adjacent sub-pixels 21, 22 and 23 through the charge generation layer CGL1 and CGL2. In some implementations, however, the trench as described above may be formed between the sub-pixels 21, 22 and 23. The formation length of the common light emitting layer 5 at the boundary of the sub-pixels 21, 22 and 23 may be increased through the trench, thereby lengthening the current path. Accordingly, the occurrence of lateral leakage current may be prevented. Furthermore, the common light emitting layer 5 may be separated from the trench, thereby preventing lateral leakage current in advance.

FIG. 5 is an enlarged cross-sectional view of Q1 area shown in FIG. 2. FIG. 5 shows a detailed cross-sectional view of the first non-emission area NEA1, the second non-emission area NEA2 and the second emission area EA2 shown in FIG. 3.

Referring to FIG. 5, the hole of the second insulating layer 3b in which the second via VIA2 is formed may include one inclined surface. The second via VIA2 may be filled in the hole of the second insulating layer 3b. After the second via VIA2 fills in the hole of the second insulating layer 3b, some portion of the second via VIA2 may be disposed even on an upper surface near the hole of the second insulating layer 3b. During a planarization process, some of the second via VIA2 disposed on the upper surface near the hole of the second insulating layer 3b may be eliminated. In the planarization process, the thickness of the second insulating layer 3b may be partially decreased. Unlike the case where the planarization process is applied when the second via VIA2 is formed, the planarization process may not be applied when electrode patterns are formed in the first through-hole TH1 and the second through-hole TH2. For example, referring to FIGS. 3 and 5, the second reflective electrode 42b and the third reflective electrode 42c may be formed in the first through-hole TH1 and the second through-hole TH2, respectively. As described above, the first reflective electrode 42a, the second reflective electrode 42b and the third reflective electrode 42c may be designed to have a separation distance d1, d2 and d3 so as to satisfy the micro cavity characteristics of the second electrode 6. After the first reflective electrode 42a is formed, the thickness of each of the insulating layers 3c and 3d disposed on the first reflective electrode 42a may be an important factor in controlling the separation distance d1, d2 and d3. Accordingly, unlike the second via VIA2, the planarization process may be omitted when the second electrode pattern (including the second reflective electrode 42b) and the third electrode pattern (including the third reflective electrode 42c) are formed.

The first through-hole TH1 of the third insulating layer 3c may include two or more inclination surfaces. For example, the first through-hole TH1 may include a first inclined surface 3cs1; and a second inclined surface 3cs2 above the first inclination surface 3cs1. The first inclined surface 3cs1 and the second inclined surface 3cs2 may be connected to each other. A lower end of the first inclined surface 3cs1 may be in direct contact with the first connection electrode 42a′. The slopes (or slope angles) of the first inclined surface 3cs1 and the second inclined surface 3cs2 may be different from each other. For example, the slope a11 of the first inclined surface 3cs1 may be greater than the slope a12 of the second inclined surface 3cs2. The third insulating layer 3c may have a first thickness H1. However, the embodiments of the present disclosure are not limited thereto and the slope a11 of the first inclined surface 3cs1 may be smaller than the slope a12 of the second inclined surface 3cs2.

The second electrode pattern may be disposed on the third insulating layer 3c. The second electrode pattern may be formed by physical vapor deposition PVD, but the embodiments of the present disclosure are not limited thereto. For example, the second reflective electrode 42b may be disposed on the third insulating layer 3c. The second reflective electrode 42b may be disposed continuously and integrally formed within the first through-hole TH1.

If the slop of the inclined surface of the first through-hole TH1 is steep, the second reflective electrode 42b may break within the first through-hole TH1 due to limitations of the deposition equipment and the deposition process. To improve reliability and avoid the break or disconnection of the second reflective electrode 42b, it can be considered that an auxiliary via is filed in the first through hole TH1 and the second reflective electrode 42b is disposed on the via within the first through hole TH1. However, when the electrode patterns are formed in the first through hole TH1 and the second through hole TH2 as described above, the planarization process may not be applied to precisely satisfy the micro cavity characteristics.

In recognition of the above, according to the display panel 100 of one embodiment, the slopes a11 and a12 of the inclined surfaces 3sc1 and 3cs2 are each 80 degrees or less, and the slope a12 of the second inclined surface 3cs2 is smaller than the slope a11 of the first inclined surface 3cs1. Thus, it is possible to improve the disconnection of the second reflective electrode 42b (or the second electrode pattern) when the first through hole TH1 starts.

Similarly, the second through hole TH2 of the fourth insulating layer 3d may include two or more inclined surfaces. For example, the second through hole TH2 may include a third inclined surface 3ds1 (or a first inclined surface of the second through hole TH1); and a fourth inclined surface 3ds2 (or a second inclined surface of the second through hole TH2) disposed above the third inclined surface 3ds1.

The third inclined surface 3ds1 and the fourth inclined surface 3ds2 may be connected to each other. A lower end of the third inclined surface 3ds1 may be in direct contact with the second reflective electrode 42b. The slopes (or slope angles) of the third inclined surface 3ds1 and the fourth inclined surface 3ds2 may be different from each other. For example, the slope a21 of the third inclined surface 3ds1 may be greater than the slope a22 of the fourth inclined surface 3ds2. The fourth insulating layer 3d may have a second thickness H2. The second thickness H2 may be greater than the first thickness H1. However, the embodiments of the present disclosure are not limited thereto and the slope a21 of the third inclined surface 3ds1 may be smaller than the slope a22 of the fourth inclined surface 3ds2.

The third electrode pattern may be disposed on the fourth insulating layer 3d. The third electrode pattern may be formed by physical vapor deposition PVD, but the embodiments of the present disclosure are not limited thereto. For example, the third connection electrode 42c′ may be disposed on the fourth insulating layer 3d. The third common electrode 42c′ may be disposed continuously and integrally formed within the second through-hole TH2.

Like the first through hole TH1, if the slope of the inclined surface of the second through-hole TH2 is steep, the second connection electrode 42c′ may break within the second through-hole TH2 due to limitations of the deposition equipment and the deposition process. In particular, since the depth of the second through hole TH2 is deeper than that of the first through hole TH1, the third connection electrode 42c′ may be more easily disconnected than the second reflective electrode 42b. To avoid the break or disconnection of the third reflective electrode 42c′, it can be considered that an auxiliary via may be filed in the second through hole TH2 and the second reflective electrode 42b is disposed on the via within the second through hole TH2. However, when the electrode patterns are formed in the first through hole TH1 and the second through hole TH2 as described above, the planarization process may not be applied to precisely satisfy the micro cavity characteristics.

In recognition of the above, according to the display panel 100 of one embodiment, the slopes a21 and a22 of the inclined surfaces 3dc1 and 3ds2 are each 80 degrees or less, and the slope a22 of the fourth inclined surface 3ds2 is smaller than the slope a21 of the third inclined surface 3ds1. Thus, it is possible to improve the disconnection of the third connection electrode 42c′ (or the third electrode pattern) when the second through hole TH2 starts.

Hereinafter, a method of manufacturing the display panel 100 according to one embodiment will be described.

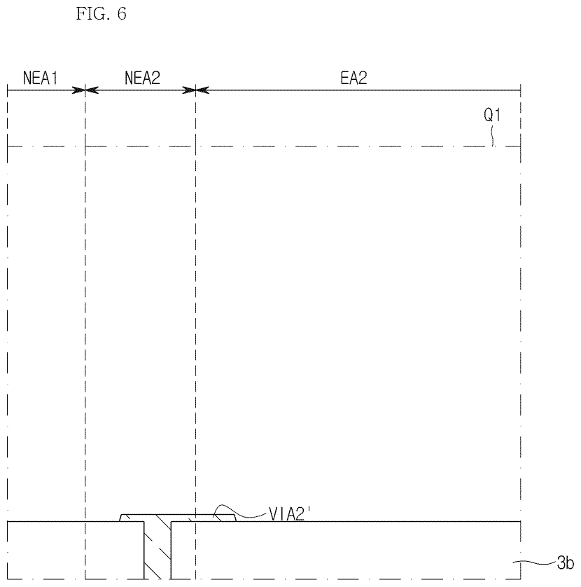

FIGS. 6 to 13 illustrate cross-sectional views for process a display panel according to one embodiment.

Referring to FIGS. 5 and 6, the second via VIA2′ is filled in the hole of the second insulating layer 3b. As shown in FIG. 6, the second via VIA2′ may be formed on the upper surface of the second insulating layer 3b near the hole. The second via VIA2′ is located inside the hole of the second insulating layer 3b and over the upper surface of the second insulating layer.

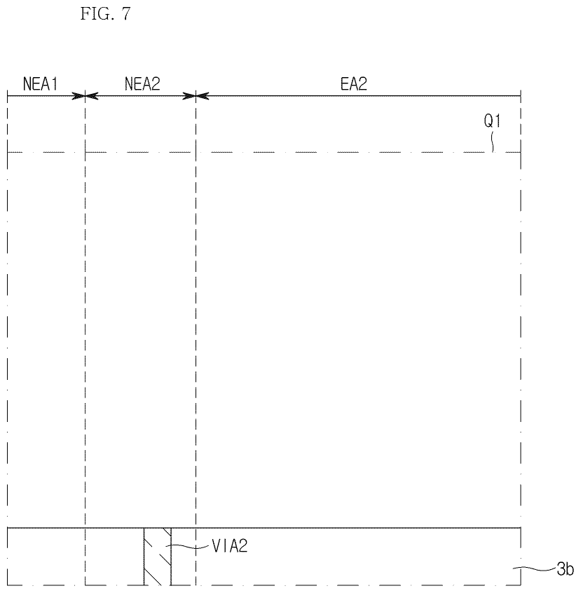

Referring to FIGS. 5 and 7, through the planarization process, the second via (see VIA2′ of FIG. 6) formed on the upper surface of the second insulating layer 3b near the hole may be eliminated to form the second via VIA2. In the planarization process, the thickness of the second insulating layer 3b may be reduced. The second via VIA2 may include at least one of copper Cu or tungsten W, but the embodiments of the present disclosure are not limited thereto.

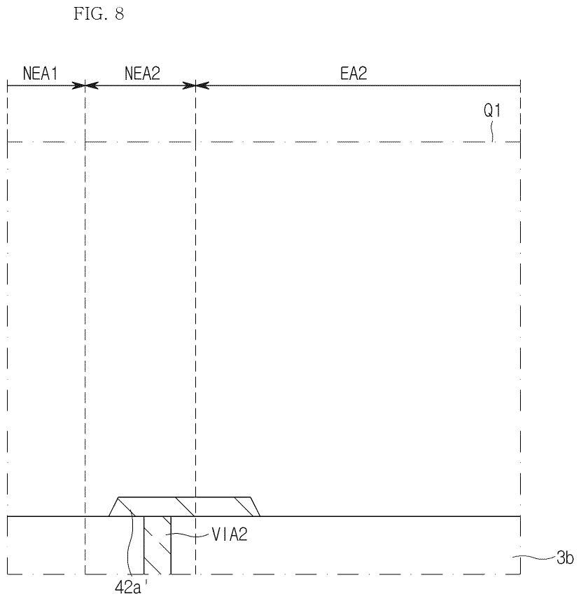

Hence, referring to FIGS. 5 and 8, the first electrode pattern may be formed on the second insulating layer 3b and the second via VIA2. The first electrode pattern may include the first connection electrode 42a′. The first electrode patterns may include a reflective material for reflecting light. For example, the reflective material may be or include a metal material, but the embodiments are not limited thereto and it may be or include other materials as long as material is capable of reflecting light. For example, the reflective material may include aluminum Al, silver Ag or a stack structure of aluminum Al and silver Ag, but the embodiments of the present disclosure are not limited thereto.

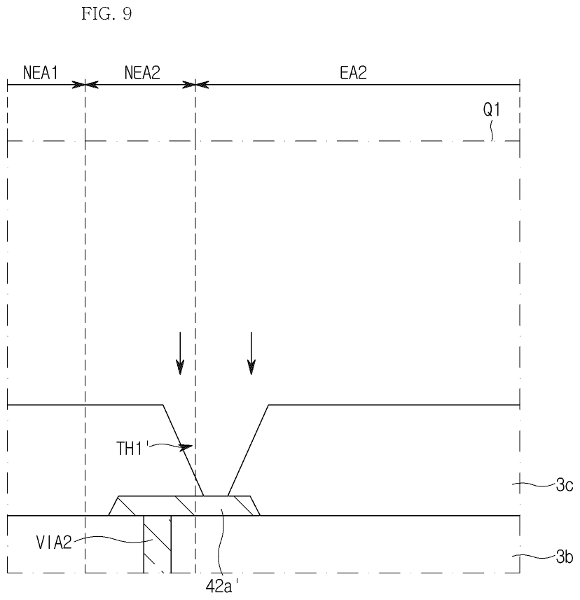

Next, referring to FIGS. 5 and 9, a photoresist is formed on the third insulating layer 3c and then the first through hole TH1′ penetrating the third insulating layer 3c may be formed. The first through hole TH1′ may be formed by etching the area exposed by the photoresist. For example, the etching for forming the first through hole TH1′ may be wet etching but the embodiments of the present disclosure are not limited thereto.

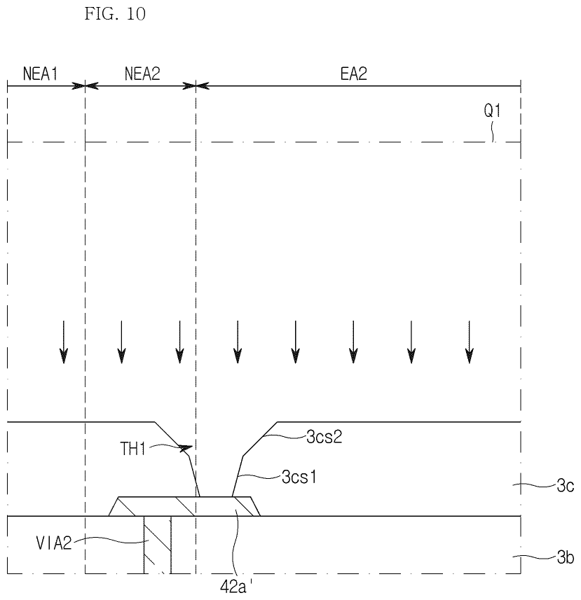

Hence, referring to FIGS. 5 and 10, the first through hole TH1 may be formed. The process of forming the first through hole TH1 may be formed by etching the front surface of the third insulating layer 3c. The etching of FIG. 10 may be performed by, for example, dry etching, but the embodiments of the present disclosure are not limited thereto. Through the etching of FIG. 10, the first inclined surface 3cs1 and the second inclined surface 3cs2 as described above referring to FIG. 5 may be formed. Compared to the first through hole TH1′ of FIG. 9, the first through hole TH1 may have a larger width. In the etching process of FIG. 10, the thickness of the third insulating layer 3c may be thinner than that of the third insulating layer 3c of FIG. 9.

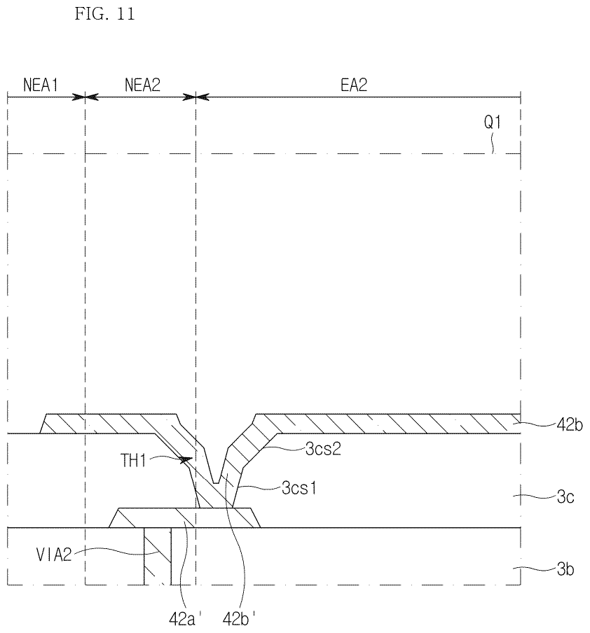

Referring to FIGS. 5 and 11, the second electrode pattern may be formed on the first insulating layer 3c and the first through hole TH1. The second electrode pattern may include the second reflective electrode 42b and the second connection electrode 42b′. The second electrode patterns may include a reflective material for reflecting light. For example, the reflective material may be or include a metal material but the embodiments are not limited thereto. It may be or include other materials as long as material is capable of reflecting light. For example, the reflective material may include aluminum Al, or silver Ag or a stack structure of aluminum Al and silver Ag, but the embodiments of the present disclosure are not limited thereto.

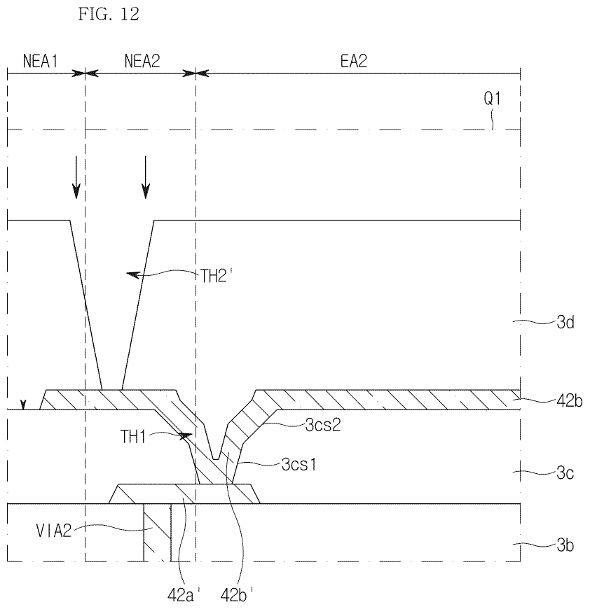

Hence, referring to FIGS. 5 and 12, a photoresist is formed on the fourth insulating layer 3d and then the second through hole TH2′ may be formed to penetrate the fourth insulating layer 3d. After a photoresist is formed on the fourth insulating layer 3d, the second through hole TH2′ may be formed by etching the area exposed by the photoresist. For example, the etching for forming the second through hole TH2′ may be performed by, for example, wet etching but the embodiments of the present disclosure are not limited thereto.

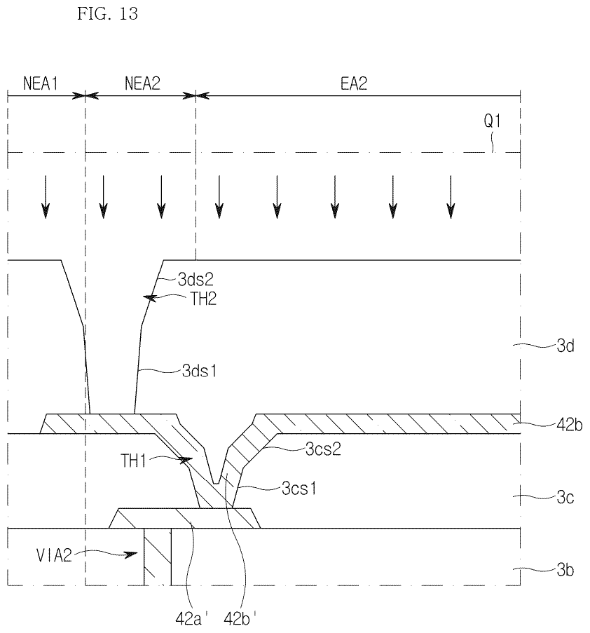

Hence, referring to FIGS. 5 and 13, the second through hole TH2 may be formed. The process of forming the second through hole TH2 may be formed by etching the front surface of the fourth insulating layer 3d. The etching of FIG. 13 may be performed by, for example, dry etching, but the embodiments of the present disclosure are not limited thereto. Through the etching of FIG. 13, the third inclined surface 3ds1 and the fourth inclined surface 3ds2 as described above referring to FIG. 5 may be formed. Compared to the second through hole TH2′ of FIG. 12, the second through hole TH2 may have a larger width. In the etching process of FIG. 13, the thickness of the fourth insulating layer 3d may be thinner than that of the fourth insulating layer 3d of FIG. 13.

Hereinafter, a display device according to another embodiment will be described. In explanting embodiments below, detailed descriptions or repeated descriptions of the configurations which are identical or similar to those described in FIGS. 1 to 13 will be omitted.

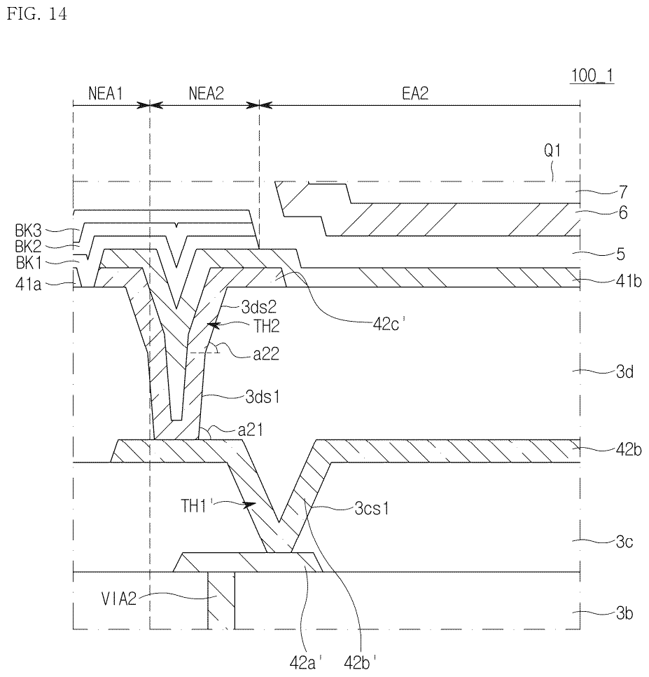

FIG. 14 is a cross-sectional view of a display device according to another embodiment of the disclosed technology.

Referring to FIG. 14, a third insulating layer 3c of a display panel 100_1 provided in the display device according to this embodiment may include a first through hole TH1′, not the first through hole TH1 of FIG. 9, which is different from the display panel 100 of FIG. 9. The first through hole TH1′ may correspond to the hole formed in FIG. 9.

As described above referring to FIG. 9, the thickness of the fourth insulating layer 3d is greater than that of the third insulating layer 3c. Accordingly, a third electrode pattern (or a third connection electrode 42c′) disposed in a second through hole TH2 of a fourth insulating layer 3d may be easily disconnected, compared to the first through hole TH1′ of the first insulating layer 3c. Accordingly, to improve the disconnection of the third electrode pattern (or the third connection electrode 42′c) in the second through hole TH2, the second through hole TH2 may include two or more inclined surfaces, but the first through hole TH1′ may include one inclined surface (see 3cs1.

The description on other components, which is identical to the description of FIG. 9, will be omitted.

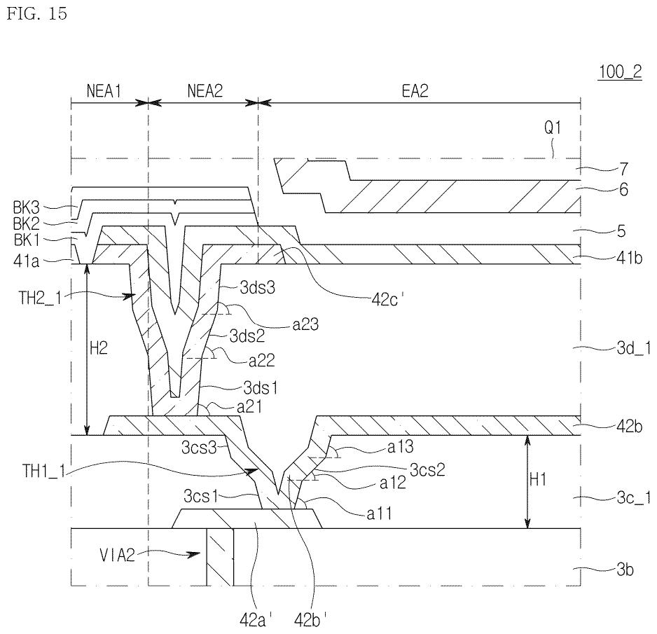

FIG. 15 is a cross-sectional view of a display device according to a further embodiment of the disclosed technology.

Referring to FIG. 15, a third insulating layer 3c_1 of a display panel 100_2 provided in the display device according to this embodiment may include a first through hole TH1_1, and a fourth insulating layer 3d_1 may include a second through hole TH2_1, which is different from the display panel 100 of FIG. 9.

In some implementations, the first through hole TH1_1 may further include a fifth inclined surface 3cs3 (or a third inclined surface of the first through hole TH1_1). The slope a13 of the fifth inclined surface 3cs3 may be greater than the slope a12 of the second inclined surface 3cs2, but the embodiments of the present disclosure are not limited thereto. The slope a13 of the fifth inclined surface 3cs3 may be 80 degrees or less. the second through hole TH2_1 may further include a sixth inclined surface 3ds3 (or a third inclined surface of the second through hole TH2_1). The slope a23 of the sixth inclined surface 3ds3 may be greater than the slope a22 of the fourth inclined surface. The slope a23 of the sixth inclined surface 3ds3 may be greater than the slope a22 of the fourth inclined surface 3ds2, but the embodiments of the present disclosure are not limited thereto. The slope a23 of the sixth inclined surface 3ds3 may be 80 degrees or less. The first and second through holes TH1-1 and TH2-1 may have the inclined surfaces having different slopes, thereby improving the disconnection of the electrode pattern disposed in the through holes TH1_1 and TH2_1 more. For example, when the first and second through holes TH1_1 and TH2_1 include three inclined surfaces having different slopes, respectively, the overall slopes may be made gentler compared to those including the inclined surfaces with two different slopes. In addition, the overall thickness of the through holes TH1_1 and TH2_1 can be smaller than the overall thickness of the through holes TH1 and Th2 of FIG. 5.

The description on other components, which is identical to that of FIG. 9, will be omitted.

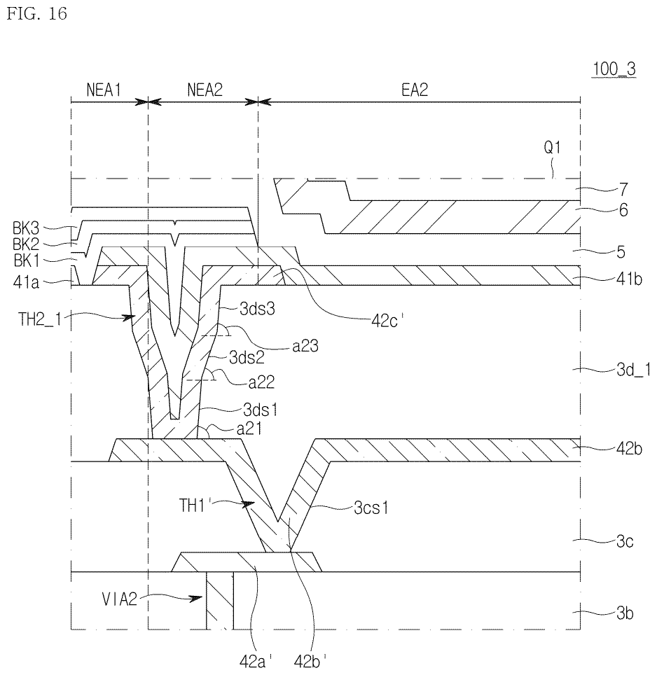

FIG. 16 is a cross-sectional view of a display device according to a still further embodiment of the disclosed technology.

Referring to FIG. 16, a third insulating layer 3c of a display panel 100_3 provided in the display device according to this embodiment may not include the first through hole TH1 of FIG. 9 but the first through hole TH1′, which is different from the display panel 100_2 of FIG. 15. The first through hole TH1′ may be a hole formed in FIG. 9.

As described in FIG. 9, the thickness of the fourth insulating layer 3d may be greater than that of the third insulating layer 3c, a third electrode pattern (or a third connection electrode 42c′) disposed in the second through hole TH2_1 of the fourth insulating layer 3d may be more easily disconnected than the second electrode pattern (or the second connection electrode 42b′) disposed in the first through hole TH1′ of the third insulating layer 3c. accordingly, to improve the disconnection of the third electrode pattern (or the third connection electrode 42c′) in the second through hole TH2_1, the second through hole TH2 may include three inclined surfaces but the first through hole TH1′ may include one inclined surface (see 3cs1).

The description on other components, which is identical to that of FIGS. 9 and 15, will be omitted accordingly.

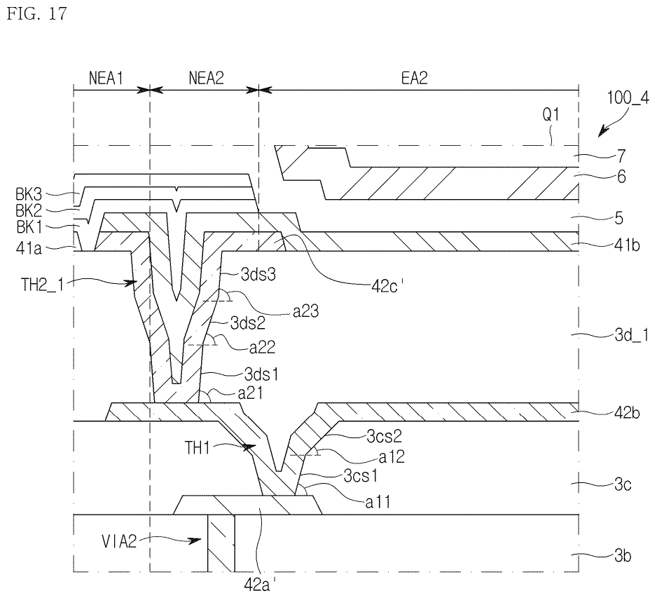

FIG. 17 is a cross-sectional view of a display device according to a still further embodiment of the disclosed technology.

Referring to FIG. 17, a fourth insulating layer 3d_1 of a display panel 100_4 provided in the display device according to this embodiment may include a second through hole TH2_1, which is different from the display panel 100 of FIG. 9.

In some implementations, the second through hole TH2_1 may further include a sixth inclined surface 3ds3 (or a second through hole TH_1). The slope a23 of the sixth inclined surface 3ds3 may be greater than the slope a22 of the fourth inclined surface 3ds2, but the embodiments of the present disclosure are not limited thereto. The slope a23 of the sixth inclined surface 3ds3 may be 80 degrees or less the second through hole TH2_1 may include three inclined surfaces with different slopes, thereby improving the disconnection of the electrode pattern disposed in the second through hole TH2_1 more. The effect generated by the second through hole TH2_1 including the three inclined surfaces having the slopes different from each other is already described in the description of FIG. 15 and it will be omitted accordingly.

The description on other components, which is identical to the corresponding description of FIG. 9, will be omitted.

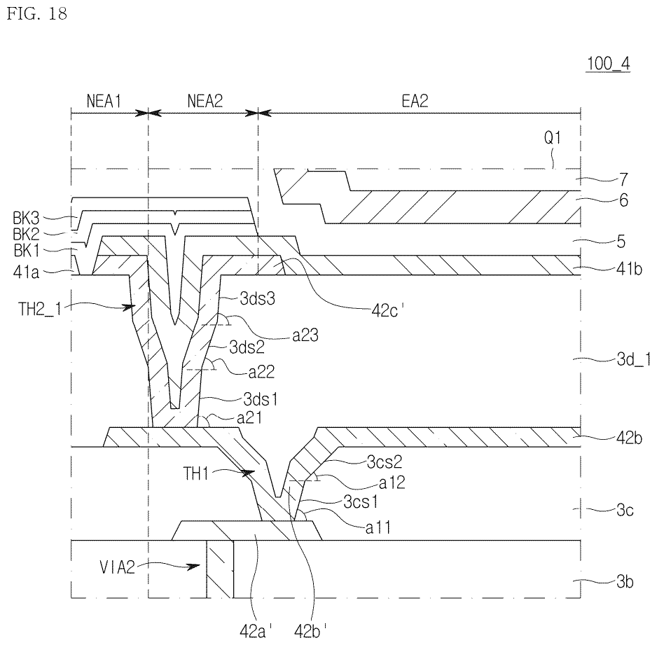

FIG. 18 is a cross-sectional view of a display device according to a still further embodiment of the disclosed technology.

Referring to FIG. 18, a third insulating layer 3c_2 of a display panel 100_5 provided in the display device according to this embodiment may include a first through hole TH1_2 and a fourth insulating layer 3d_2 may include a second through hole TH2_2, which is different from the display panel 100_2 of FIG. 15.

In some implementations, the first through hole TH1_2 may include a first inclined surface 2cs_1, a second inclined surface 3cs_1 and a fifth inclined surface 3cs_1 (or a third inclined surface of a first through hole TH1_2). The second through hole TH2_2 may include a third inclined surface 3cs_1 (or a first inclined surface of a second through hole TH2_2), a fourth inclined surface 3ds2_1 (or a second inclined surface of a second through hole TH2_2) and a sixth inclined surface 2ds3_1 (or a third inclined surface of a second through hole TH2_2). In case of the first through hole TH1_1, the slope may become larger from a top toward a bottom (a13_1<a12_1<a11_1). The slopes a11_1, a12_1, a13_1, a21_1, a22_1 and a23_1 of the inclined surfaces of the first through hole TH1_1 and the second through hole TH2_1 may be 80 degrees or less.

The description on other components, which is identical to the corresponding description of FIG. 15, will be omitted.

The display device according to the various embodiments of the present disclosure may be described as follows.

The display device may include a substrate including an emission area and a non-emission area disposed adjacent to the emission area; a reflective electrode disposed on the substrate; an auxiliary layer disposed on the reflective electrode; and an organic light emitting element disposed on the auxiliary layer.

In the display according to various embodiments of the present disclosure, the reflective electrode may be disposed on the emission area and some of the non-emission area.

In the display according to the various embodiments of the present disclosure, the auxiliary layer may be in direct contact with an upper surface of the reflective electrode in the non-emission area.

In the display device according to the various embodiments of the present disclosure, the organic light emitting element may include an anode electrode disposed on the reflective electrode and the auxiliary layer; a common light emitting layer disposed on the anode electrode; and a second electrode disposed on the common light emitting layer.

The display device according to the various embodiments of the present disclosure may further include banks disposed between the anode electrode and the common light emitting layer, and the banks may be disposed on the non-emission area.

In the display device according to the various embodiments of the present disclosure, a second distance between the reflective electrode and the second electrode in the non-emission area may be greater than a first distance between the reflective electrode and the second electrode in the emission area.

In the display device according to the various embodiments of the present disclosure may include a metal material, and the light reflectance of the auxiliary layer may be lower than the light reflectance of the reflective electrode.

In the display device according to the various embodiments of the present disclosure, the light absorption rate of the auxiliary layer may be greater than the light absorption rate of the reflective electrode.

In the display device according to the various embodiments of the present disclosure, the auxiliary layer may include a light blocking material.

In the display device according to the various embodiments of the present disclosure, the light transmittance of the auxiliary layer may be greater than the light transmittance of the reflective electrode.

In the display device according to the various embodiments of the present disclosure, the thickness (t1) of the auxiliary layer and the thickness (t2) of the bank satisfy the following equation:

(t1+t2)=λ/2×(2 m) (here, t1 is the thickness of the auxiliary layer, t2 is the thickness of the bank, and A is the target wavelength of the light-emitting region.)

In the display device according to the various embodiments of the present disclosure, the reflective electrode may be disposed on the emission area and the non-emission area, and may further include a transistor disposed between the substrate and the reflective electrode on the non-emission area. The reflective electrode may be connected to the transistor on the non-emission area.

In the display device according to the various embodiments of the present disclosure, the auxiliary layer may overlap with the transistor.

In the display device according to the various embodiments of the present disclosure, the auxiliary layer may be configured to expose an upper surface of the reflective layer partially, and the anode electrode may be connected to the exposed upper surface of the reflective electrode.

While various embodiments have been described with reference to the exemplified drawings, variations and improvements of the disclosed embodiments and other embodiments may be made based on what is described or illustrated in this document.

What is claimed is:

1. A display device comprising:
a substrate;
a first insulating layer disposed over the substrate;
a circuit area disposed in the first insulating layer;
a connection electrode disposed on the first insulating layer and electrically connected to the circuit area;
a second insulating layer disposed on the connection electrode;
a first electrode pattern disposed on the second insulating layer and electrically connected to the connection electrode;
a third insulating layer disposed on the first electrode pattern;
a second electrode pattern disposed on the third insulating layer in a first through hole of the third insulating layer and electrically connected to the first electrode pattern;
a fourth insulating layer disposed on the second electrode pattern; and
a third electrode pattern disposed on the fourth insulating layer and in a second through hole of the fourth insulating layer, the third electrode pattern electrically connected to the second electrode pattern,
wherein at least one of the first through hole or the second through hole includes at least two inclined surfaces having slopes different from each other.

2. The display device of claim 1, wherein the second through hole comprises a first inclined surface disposed on the second electrode pattern; and a second inclined surface connected to the first inclined surface, and
a slope of the first inclined surface of the second through hole is greater than a slope of the second inclined surface of the second through hole.

3. The display device of claim 2, wherein the second through hole further comprises a third inclined surface disposed on a second inclined surface of the second through hole, and a slope of the third inclined surface is greater than a slope of the second inclined surface of the second through hole.

4. The display device of claim 2, wherein the first through hole comprises a first inclined surface disposed on the first electrode pattern; and a second inclined surface connected to the first inclined surface, and
a slope of the first inclined surface of the first through hole is greater than a slope of the second inclined surface of the first through hole.

5. The display of claim 4, wherein the first through hole further comprises a third inclined surface on a second inclined surface of the first through hole, and
a slope of the third inclined surface of the first through hole is greater than a slope of the second inclined surface of the first through hole.

6. The display device of claim 1, wherein the second through hole comprises a first inclined surface disposed on the second electrode pattern; a second inclined surface connected to the first inclined surface; and a third inclined surface connected to the second inclined surface.

7. The display device of claim 6, wherein the slope of the first inclined surface of the second through hole is greater than the slope of the second inclined surface of the second through hole, and
the slope of the second inclined surface of the second through hole is greater than the slope of the third inclined surface of the second through hole.

8. The display device of claim 1, wherein a thickness of the fourth insulating layer is greater than a thickness of the third insulating layer.

9. The display device of claim 1, wherein the second through hole comprises three or more inclined surfaces having slopes different from one another, and
the first through hole comprises one inclined surface or two inclined surfaces having slopes different from each other.

10. The display device of claim 1, wherein a first sub-pixel, a second sub-pixel and a third sub-pixel are provided on the substrate,
the first electrode pattern comprises a first reflective electrode of the first sub-pixel; and first connection electrodes of the first sub-pixel to the third sub-pixel,
the second electrode comprises second connection electrodes of the first sub-pixel to the third sub-pixel; and a second reflective electrode of the second sub-pixel, and
the third electrode pattern comprises third connection electrodes of the first sub-pixel to the third sub-pixel; and a third reflective electrode of the third sub-pixel.

11. The display device of claim 10, wherein each of the first sub-pixel, the second sub-pixel and the third sub-pixel comprises an emission area; and a non-emission area disposed adjacent to the emission area, and
the first reflective electrode, the second reflective electrode and the third reflective electrode are disposed on the emission area of each sub-pixel.

12. The display device of claim 1, further comprising:
a first electrode disposed on the third electrode pattern and being in direct contact with the third electrode pattern.

13. The display device of claim 12, further comprising:
a common light emitting layer disposed on the first electrode; and
a second electrode disposed on the common light emitting layer.

14. A display device comprising:
a substrate;
a first sub-pixel, a second sub-pixel and a third sub-pixel that are defined on the substrate, each of the first sub-pixel, the second sub-pixel, and the third sub-pixel configured to emit a corresponding colored light;
a first reflective electrode disposed on the substrate of the first sub-pixel;
first connection electrodes disposed on the substrate of the first sub-pixel to the third sub-pixel;
a first insulating layer disposed on the first reflective electrode and the first connection electrodes;
second connection electrodes disposed on the first insulating layer of the first sub-pixel to the third sub-pixel;
a second reflective electrode disposed on the first insulating layer of the second sub-pixel;
a second insulating layer disposed on the second reflective electrode and the second connection electrodes;
third connection electrodes disposed on the second insulating layer of the first sub-pixel to the third sub-pixel;
a third reflective electrode disposed on the second insulating layer of the third sub-pixel;
a first electrode disposed on the third connection electrodes and the third reflective electrode;
a common light emitting layer disposed on the first electrode; and
a second electrode disposed on the common light emitting layer,
wherein a distance between the first reflective electrode and the second electrode is greater than a distance between the second reflective electrode and the second electrode,
a distance between the second reflective electrode and the second electrode is greater than a distance between the third reflective electrode and the second electrode,
the first insulating layer comprises a third through hole and the second insulating layer comprises a second through hole, and
the first through hole or the second through hole comprises at least two inclined surfaces having slopes different from each other.

15. The display device of claim 14, wherein the second through hole comprises a first inclined surface disposed on the second connection electrode and a second inclined surface connected to the first inclined surface, and
a slope of the first inclined surface of the second through hole is greater than a slope of the second inclined surface of the second through hole.

16. The display device of claim 15, wherein the second through hole further comprises a third inclined surface disposed on the second inclined surface of the second through hole, and
a slope of the third inclined surface is greater than a slope of the second inclined surface of the second through hole.

17. The display device of claim 15, wherein the first through hole comprises a first inclined surface disposed on the first connection electrode and a second inclined surface connected to the first inclined surface, and
a slope of the first inclined surface of the first through hole is greater than a slope of the second inclined surface of the first through hole.

18. The display device of claim 17, wherein the first through hole further comprises a third inclined surface disposed on the second inclined surface of the first through hole, and
a slope of the third inclined surface of the first through hole is greater than a slope of the second inclined surface of the first through hole.

19. The display device of claim 14, wherein the second through hole comprises a first inclined surface disposed on the second connection electrode; a second inclined surface connected to the first inclined surface; and a third inclined surface connected to the second inclined surface, and
a slope of the first inclined surface of the first through hole is greater than a slope of the second inclined surface of the second through hole, and a slope of the second inclined surface of the second through hole is greater than a slope of the third inclined surface of the second through hole.

20. The display device of claim 14, wherein a thickness of the second insulating layer is greater than a thickness of the first insulating layer.
